(19) United States
(12) Patent Application Publication
(10) Pub. No.: US 2026/0173415 A1
(43) Pub. Date: Jun. 18, 2026

(54) CAPACITOR STRUCTURE AND METHOD FOR FABRICATING THE SAME

(71) Applicant: United Microelectronics Corp., Hsinchu (TW)

(72) Inventors: Tse-Pu CHEN, New Taipei City (TW); Chien-Yi LEE, Hsinchu City (TW); Sheng-Huei DAI, Taitung County (TW)

(21) Appl. No.: 19/032,465

(22) Filed: Jan. 21, 2025

(30) Foreign Application Priority Data
Dec. 12, 2024 (TW) 113148489

(51) Int. Cl. H10D 1/68; H10D 1/00

(52) U.S. Cl. CPC H10D 1/714; H10D 1/043

(57) ABSTRACT

A capacity structure includes a semiconductor substrate, a first patterned conductive layer, at least one first contact plug and at least one second contact plug. The semiconductor substrate includes a first-conductivity well region and a second-conductivity well region adjacent to each other. The first patterned conductive layer is disposed on the semiconductor substrate and includes a first electrode pattern and a second electrode pattern separated from each other and forming at least one first parasitic capacitance there between. The first contact plug electrically connects the first electrode pattern and the first-conductivity well region. The second contact plug electrically connects the second electrode pattern and the second-conductivity well region, so as to form at least one second parasitic capacitance between the first-conductivity well region and the second-conductivity well region.

### BACKGROUND

This application claims the benefit of Taiwan Application Serial No. 113148489 filed at Dec. 12, 2024 the subject matter of which is incorporated herein by reference.

### Technical Field

The disclosure relates to a semiconductor device and the method for manufacturing the same, and more particularly to a capacitor structure and method for manufacturing the same.

### Description of Background

A typical integrated circuit (IC) usually contains passive components, such as capacitors. Two types of prior art capacitor structures including metal-insulator-metal (MIM) capacitors and metal-oxide-metal (MOM) capacitors are commonly used in the IC. A typical MIM capacitor includes a bottom plate (bottom layer) and an upper plate (upper layer) made of conductive material, as well as an insulating layer inserted between these two. An MIM capacitor may further include a three-dimensional structure with multiple metal layers vertically stacked with each other, in which a plurality of parallel finger-shaped electrodes are respectively formed; and these finger-shaped electrodes on each metal layer are electrically connected through contact plugs (via plugs) formed in the insulating layer.

Generally speaking, MIM capacitors have smaller parasitic capacitances, but with higher manufacturing cost because requiring additional photomasks (reticles) during the production process. The metal layers of MOM capacitors can be formed by current metal processes without additional photomasks, and the process cost is relatively low. Moreover, because MOM capacitors have a multi-layered three-dimensional structure and a high unit capacitance density, as the critical dimensions of semiconductor device shrink and device performance gradually improves, they have become one of the most widely used devices in the IC design system and its manufacturing processes; and usually are used to filter noise in radio frequency circuits (RF IC), or used as load devices in digital circuits (digital electronics).

As the critical dimensions of semiconductor manufacturing processes shrink, the integration and computing efficiency of system circuits have rapidly increased, and the capacitance density required by system circuits has also increased relatively. Increasing the number of metal layers in a three-dimensional MIM capacitor has become one of the solutions to increase capacitance density. However, the increase in the number of metal layers and the shrinkage of critical dimensions will aggravate the variability of various process parameters (such as, the thickness of each metal layer, the spacing and pitches of the finger-shaped electrodes, etc.), resulting in a decrease in the process yield of the MIM capacitors and the system circuits applying the same. How to increase the capacitance density of the capacitors without excessively increasing the manufacturing cost of the capacitors (for example, without increasing the number of conductive (metal) layers in the three-dimensional structure of the capacitors) has become an important issue in this technical field.

Therefore, there is a need of providing an advanced capacitor structure and method for manufacturing the same to obviate the drawbacks encountered from the prior art.

### SUMMARY

One aspect of the present disclosure is to provide a capacitor structure, wherein the capacity structure includes a semiconductor substrate, a first patterned conductive layer, at least one first contact plug and at least one second contact plug. The semiconductor substrate includes a first-conductivity well region and a second-conductivity well region adjacent to each other. The first patterned conductive layer is disposed on the semiconductor substrate and includes a first electrode pattern and a second electrode pattern separated from each other and forming at least one first parasitic capacitance there between. The first contact plug electrically connects the first electrode pattern and the first-conductivity well region. The second contact plug electrically connects the second electrode pattern and the second-conductivity well region, so as to form at least one second parasitic capacitance between the first-conductivity well region and the second-conductivity well region.

Another aspect of the present disclosure is to provide a method for manufacturing a capacitor structure, wherein the method includes steps as follows: Firstly, a semiconductor substrate including a first-conductivity well region and a second-conductivity well region adjacent to each other is provided. Then, a first patterned conductive layer is formed on the semiconductor substrate, wherein the first patterned conductive layer includes a first electrode pattern and a second electrode pattern separated from each other and forming a first parasitic capacitance there between. At least one first contact plug is formed to electrically connect the first electrode pattern and the first-conductivity well region; and at least one second contact plug is formed to electrically connect the second electrode pattern to the second-conductivity well region, thereby a second parasitic capacitance is formed between the first-conductivity well region and the second-conductivity well region.

In accordance with the aforementioned embodiments of the present disclosure, a capacitor structure and a manufacturing method thereof are provided. An electrode layer having a first electrode pattern and a second electrode pattern separated from each other is firstly formed on a semiconductor substrate, wherein at least one first parasitic capacitance is formed between the first electrode pattern and the second electrode pattern. The first electrode pattern is then electrically connected to the first-conductivity well region of the semiconductor substrate using at least one first contact plug; the second electrode pattern is electrically connected to the second-conductivity well region in the semiconductor substrate using at least one second contact plug; and at least one second parasitic capacitance is thus formed between the first-conductivity well region and the second-conductivity well region. Through the adding of the at least one second parasitic capacitance, the capacitance density of the capacitor structure can be increased without increasing the number of metal layers in the three-dimensional structure of the capacitor structure, thereby saving the manufacturing cost of the capacitor structure.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIGS. 1A to 1E are diagrams illustrating a series of process structures for manufacturing a capacitor structure, according to one embodiment of the present disclosure;

FIG. 2 is a perspective view of the capacitor structure as shown in FIG. 1E; and

FIG. 3 is a partial equivalent circuit diagram based on the capacitor structure as shown in FIG. 1C.

### DETAILED DESCRIPTION

The embodiments as disclosed below provide a capacitor structure and a manufacturing method thereof, which can increase capacitance density without increasing the number of conductive (metal) layers in the three-dimensional structure of the capacitor structure. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

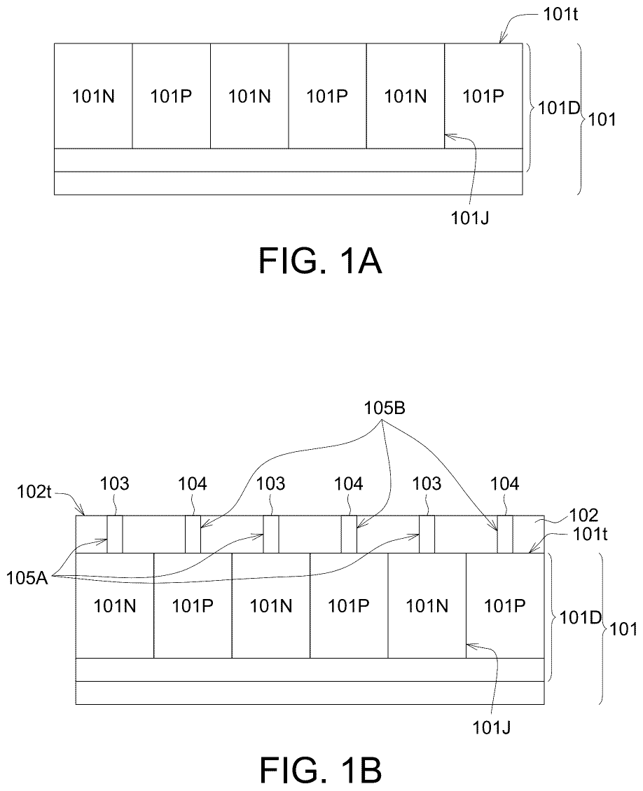

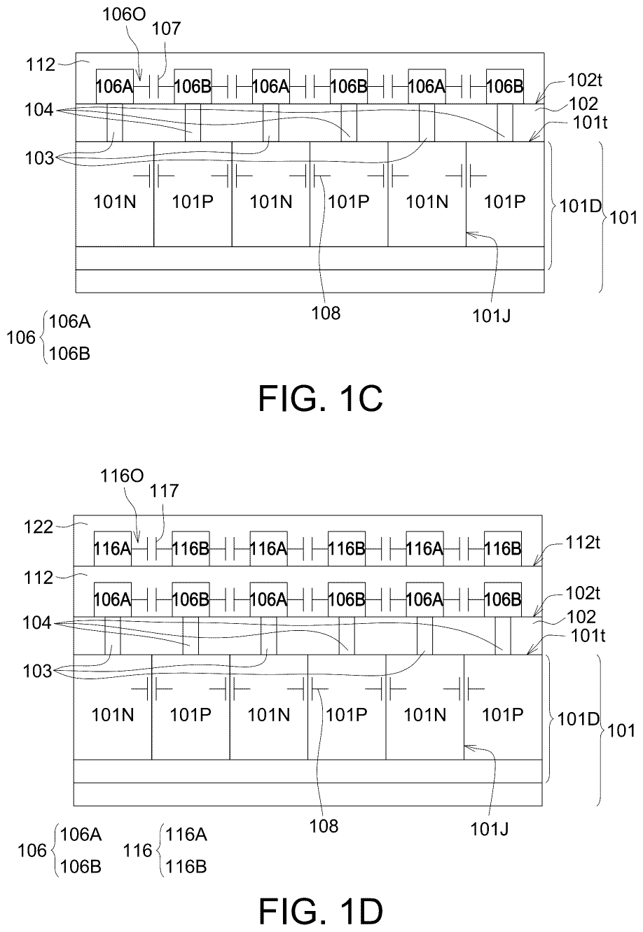

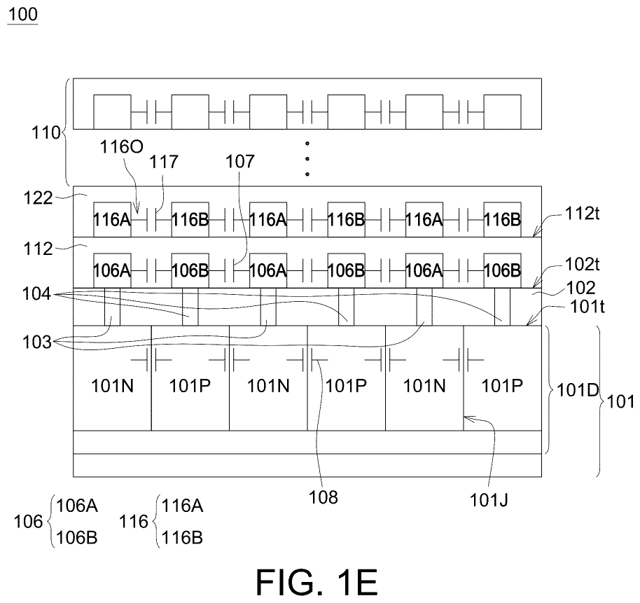

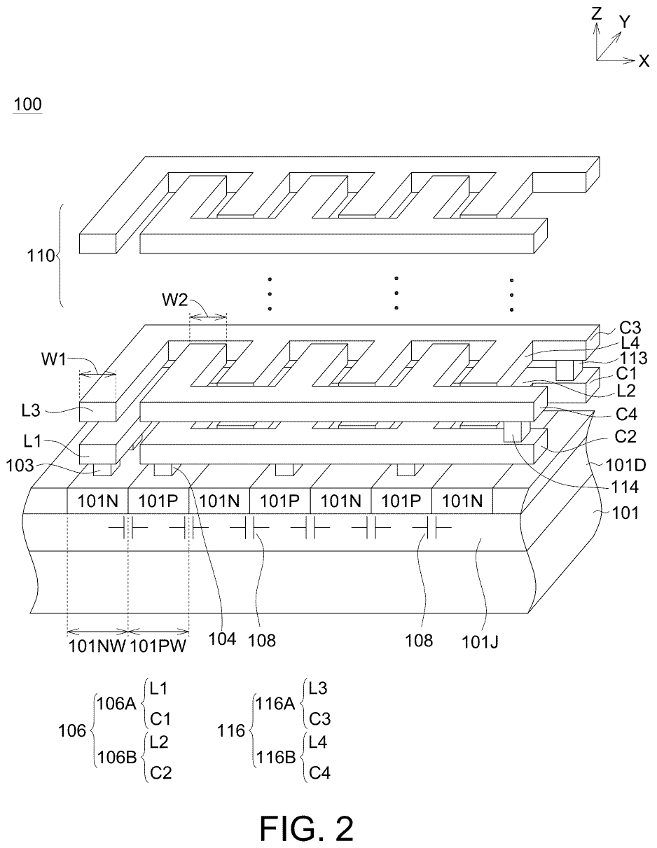

FIGS. 1A to 1E are diagrams illustrating a series of process structures for manufacturing a capacitor structure 100, according to one embodiment of the present disclosure. FIG. 2 is a perspective view of the capacitor structure 100 as shown in FIG. 1E. The capacitor structure 100 may be a MIM capacitor or a MOM capacitor. The method of making the capacitor structure 100 includes steps as follows:

Firstly, a semiconductor substrate 101 including a first-conductivity well region 101N and a second-conductivity well region 101P adjacent to each other is provided. In some embodiments of the present disclosure, the semiconductor substrate 101 may be a silicon substrate (e.g., a silicon wafer) including a first deeply doped well region 101D with the first-conductivity, a plurality of first-conductivity well regions 101N and a plurality of second-conductivity well regions 101P both connected to the first deeply doped well region 101D.

In the present embodiment, the first deeply doped well region 101D is an n-type deeply doped well region formed in the silicon semiconductor substrate 101 doped with n-type dopants (such as, antimony (Sb), arsenic (As) or phosphorus (P)). The plurality of first-conductivity well regions 101N and the plurality of second-conductivity well regions 101P respectively extend downward from the upper surface 101t of the semiconductor substrate 101 into the first deeply doped well region 101D (as shown in FIG. 1A).

Each of the first-conductivity well regions 101N may be an n-type doped well region doped with n-type dopants (such as, Sb, As or P); each of the second-conductivity well region may be a p-type doped well region doped with p-type dopants (such as, aluminum (Al), boron (B) or gallium (Ga)). Each of the first-conductivity well regions 101N is adjacent to one of the plurality of second-conductivity well regions 101P, so as to form a p-n junction 101J between them. Wherein, the doping concentration of the first deeply doped well region 101D is smaller than the doping concentrations of the first-conductivity well regions 101N and the second-conductivity well region 101P; and the depth of the first deeply doped well region 101D extending into the silicon semiconductor substrate 101 is deeper than the depths of the first-conductivity well regions 101N and the second-conductivity well region 101P extending into the silicon semiconductor substrate 101.

Then, a first dielectric layer 102 is formed on the semiconductor substrate 101 to cover the plurality of first-conductivity well regions 101N and the plurality of second-conductivity well regions 101P. In some embodiments of the present disclosure, the first dielectric layer 102 may include a dialectic material selected from a group consisting of silicon oxide, silicon nitride, silicon carbide, silicon carbo-nitride or other high-k materials and the arbitrary combinations thereof.

Next, a plurality of first contact plugs 103 and a plurality of second contact plugs 104 are formed in the first dielectric layer 102. Each of the first contact plugs 103 passes through the first dielectric layer 102 and electrically contacts with one of the first-conductivity well regions 101N; and each of the second contact plugs 104 passes through the first dielectric layer 102 and electrically contacts with one of the second-conductivity well regions 101P (as shown in FIG. 1B).

In the present embodiment, the forming of the plurality of first contact plugs 103 and the plurality of second contact plugs 104 includes steps as follows: Firstly, a plurality of through holes 105A and 105B are formed in the first dielectric layer 102 using a photoresist etching process. The through holes 105A and 105B extend downward from the upper surface 102t of the first dielectric layer 102, each first electrical well region 101N can be partially exposed to the outside through at least one through hole 105A; and each second electrical well region 101P can It is partially exposed to the outside through at least one through hole 105B. Wherein, the plurality of through holes 105A and 105B extend downward from the upper surface 102t of the first dielectric layer 102, so as to make each of the first-conductivity well regions 101N partially exposed from the corresponding one of the through holes 105A, and to make each of the second-conductivity well regions 101P partially exposed from the corresponding one of the through holes 105B.

After that, a conductive material is formed on the upper surface 102t of the first dielectric layer 102 by performing a deposition process, and fills the plurality of through holes 105A and 105B. Subsequently, a chemical mechanical polishing (CMP) process is used to planarize the conductive material, thereby the plurality of first contact plugs 103 and the plurality of second contact plugs 104 are respectively formed in the plurality of through holes 105A and 105B. Such that, each of the first contact plugs 103 can electrically contact with the corresponding one of the first-conductivity well regions 101N respectively; and each of the second contact plugs 1043 can electrically contact with the corresponding one of the second-conductivity well regions 101P respectively.

Next, a first conductive layer 106 is formed on the upper surface 102t of the first dielectric layer 102. In some embodiments of the present disclosure, the first conductive layer 106 includes a copper metal layer. Another photoresist etching process is then performed to pattern the first conductive layer 106 to at least form a first electrode pattern 106A and a second electrode pattern 106B separated from each other. At the same time, the first electrode pattern 106A is electrically connected to each of the first-conductivity well regions 101N through each corresponding one of the first contact plugs 103; and the second electrode pattern 106B is electrically connected to each of the second-conductivity well regions 101P through each corresponding one of the second contact plugs 104. Therefore, a second parasitic capacitance 108 can be formed between each one of the first-conductivity well region 101N and the adjacent one of the second electrical well regions 101P.

Thereafter, a second dielectric layer 112 is formed on the patterned first conductive layer 106 to cover the first electrode pattern 106A and the second electrode pattern 106B, and to fill the opening 106O used to separate the first electrode pattern 106A and the second electrode pattern 106B. Thus, at least one first parasitic capacitance 107 is formed between the first electrode pattern 106A and the second electrode pattern 106B (as shown in FIG. 1C). In some embodiments of the present disclosure, the materials and methods for forming the second dielectric layer 112 may be the same as or different from that for forming the first dielectric layer 102.

For example, in some embodiments of the present disclosure, the first electrode pattern 106A and the second electrode pattern 106B are two finger-shaped electrode patterns arranged adjacent to each other in an intersecting manner. Referring to FIG. 2, the plurality of first-conductivity well regions 101N may be a plurality of first-conductivity strips formed on the semiconductor substrate 101, extending in parallel along the Y-axis direction, and separated from each other; the plurality of second-conductivity well regions 101P may be a plurality of second-conductivity strips formed on the semiconductor substrate 101, extending parallel to the Y-axis direction and separated from each other.

Wherein the plurality of first-conductivity strips (first-conductivity well regions 101N) and the plurality of second-conductivity stripes (second-conductivity well regions 101P) are arranged in a staggered manner and contact with each other. In other words, each of the first-conductivity strip (first-conductivity well region 101N) contacts with two adjacent second-conductivity strips (second-conductivity well region 101P); and each of the second-conductivity strips (second-conductivity well region 101P) contacts with two adjacent first-conductivity strip (first-conductivity well region 101N).

In the present embodiment, the first electrode pattern 106A of the patterned first conductive layer 106 includes a plurality of first finger portions L1 and a first connection portion C1. The first connection portion C1 extends along the X-axis direction; one end of each first finger portion L1 extends in parallel along the Y-axis direction; and the other end of each first finger portion L1 connects to the first connection portion C1 respectively. The second electrode pattern 106B of the patterned first conductive layer 106 includes a plurality of second finger portions L2 and a second connection portion C2. The second connection portion C2 extends along the X-axis direction; one end of each second finger portion L2 extends in parallel along the Y-axis direction; and the other end of each second finger portion L2 connects to the second connecting portion C2 respectively. Wherein, the plurality of first finger portions L1 and the plurality of second finger portions L2 are arranged in a staggered manner with each other. Thus, a first parasitic capacitance 107 can be formed between each of the first finger portions L1 and its adjacent two second finger portions L2.

Each of the first finger portions L1 is vertically arranged above a corresponding first-conductivity well region 101N (a first-conductivity strip), and is electrically connected to the corresponding first-conductivity well region 101N (the first-conductivity strip) through the corresponding one of the first contact plugs 103. Each of the second finger portions L2 is vertically arranged above a corresponding second-conductivity well region 101P (a second conductivity strip), and is electrically connected to the corresponding second-conductivity well region 101P (the second-conductivity strip) through the corresponding one of the second contact plugs 104. Thus, a second parasitic capacitance 108 can be formed on the p-n junction 101J between each of the first-conductivity well region 101N (first-conductivity strip) and its adjacent one of the second-conductivity well regions 101P (second-conductivity strip).

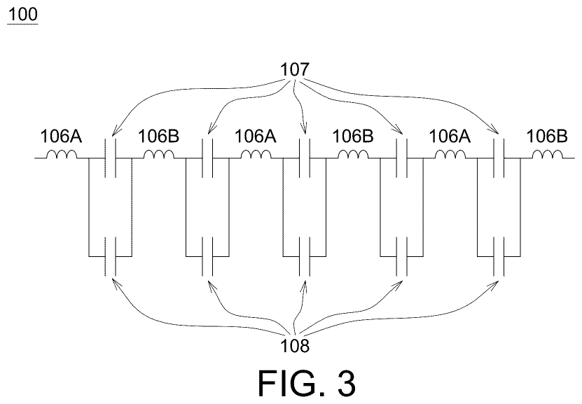

FIG. 3 is a partial equivalent circuit diagram based on the capacitor structure 100 as shown in FIG. 1C. Wherein, the capacitance value of the second parasitic capacitance 108 is substantially smaller than the capacitance value of the first parasitic capacitance 107. For example, in some embodiments, the capacitance value of the second parasitic capacitance 108 is substantially 50% of the capacitance value of the first parasitic capacitance 107.

Referring to FIG. 2 again, the lateral width W1 of each first finger portion L1 is less than or equal to the lateral width 101NW of its corresponding first-conductivity well region 101N (first-conductivity strip). The lateral width W2 of each second finger L2 is less than or equal to the lateral width 101PW of its corresponding second-conductivity well region 101P (second-conductivity strip). In the present embodiment, the lateral width W1 of each first finger L1 may be equal to the lateral width W2 of each second finger L2; and the lateral width 101NW of each first-conductivity well region 101N (first-conductivity strip) is equal to the lateral width 101PW of each second-conductivity well region 101P (second-conductivity strip). And the ratio of the lateral width W1 of each first finger portion L1 to the lateral width 101NW of each first-conductivity well region 101N (first-conductivity strip) is substantially between 0.25 to 0.75.

Afterwards, at least one third contact plug 113 and at least one fourth contact plug 114 are formed in the second dielectric layer 112 (as shown in FIG. 2). The third contact plug 113 passes through the second dielectric layer 112 and electrically contacts with the first connection portion C1 of the first electrode pattern 106A; the fourth contact plug 114 passes through the second dielectric layer 112 and electrically contacts with the second connection portion C2 of the second electrode pattern 106B. Since the forming method of the third contact plug 113 and the fourth contact plug 114 is substantially similar to that for forming the first contact plug 103 and the second contact plug 104, thus no further details descriptions thereof will be provided.

Next, a second conductive layer 116 is formed on the upper surface 112t of the second dielectric layer 112. And another photoresist etching process is performed to pattern the second conductive layer 116 to at least form a third electrode pattern 116A and a fourth electrode pattern 116B separated from each other. A third dielectric layer 122 is then formed on the patterned second conductive layer 116 to cover the third electrode pattern 116A and the fourth electrode pattern 116B, and to fill the opening 116O used to separate the third electrode pattern 116A and the fourth electrode pattern 116B. Thus, at least one third parasitic capacitance 117 is formed between the third electrode pattern 116A and the fourth electrode pattern 116B. In some embodiments of the present disclosure, the materials and method for forming the third dielectric layer 122 may be the same as or different from that for forming the first dielectric layer 102 or the second dielectric layer 112.

In some embodiments of the present disclosure, the third electrode pattern 116A and the fourth electrode pattern 116B of the patterned second conductive layer 116 are two finger-shaped electrode patterns arranged adjacent to each other in an intersecting manner, and are arranged vertically corresponding to the first electrode pattern 106A and the second electrode pattern 106B of the patterned first conductive layer 106 respectively. Wherein, the third electrode pattern 116A electrically contacts with the first electrode pattern 106A through the third contact plug 113; and the fourth electrode pattern 116B electrically contacts with the second electrode pattern 106B through the fourth contact plug 114.

For example, in the present embodiment, the third electrode pattern 116A includes a plurality of third finger portions L3 and a third connection portion C3 connecting the plurality of third finger portions L3. The plurality of third finger portions L3 are respectively arranged vertically corresponding to the plurality of first finger portions L1 of the first electrode pattern 106A; the third connection portion C3 is arranged vertically corresponding to the first connection portion C1 of the first electrode pattern 106A; and the third connection portion C of the third electrode pattern 116A is electrically connected to the first connection portion C1 of the first electrode pattern 106A through a plurality of third contact plugs 113.

The fourth electrode pattern 116B includes a plurality of fourth finger portions L4 and a fourth connection portion C4 connecting the plurality of fourth finger portions L4. Wherein, the plurality of fourth finger portions L4 are respectively arranged vertically corresponding to the plurality of second finger portions L2 of the second electrode pattern 106B; the fourth connection portion C4 is arranged vertically corresponding the second connection portion C2 of the second electrode pattern 106B; and the fourth connection portion C4 of the fourth electrode pattern 116B is electrically connected to the second connection portion C2 of the second electrode pattern 106B through a plurality of fourth contact plugs 114 (as shown in FIG. 2).

Subsequently, the steps for forming the third dielectric layer 122, the plurality of third contact plugs 113, the plurality of fourth contact plugs 114, and the patterned second conductive layer 116 can be repeated, so as to form a plurality of patterned metal stacks 110 similar to that of the patterned first conductive layer 106 and the patterned second conductive layer 116 over the patterned second conductive layer 116 and the third dielectric layer 122, and then complete the capacitor structure 100 as shown in FIGS. 1E and 2.

In accordance with the aforementioned embodiments of the present disclosure, a capacitor structure 100 and a manufacturing method thereof are provided. An electrode layer (i.e., the patterned first conductive layer 106) having a first electrode pattern 106A and a second electrode pattern 106B separated from each other is firstly formed on a semiconductor substrate 101, wherein at least one first parasitic capacitance 107 is formed between the first electrode pattern 106A and the second electrode pattern 106B. The first electrode pattern 106A is then electrically connected to the first-conductivity well region 101N of the semiconductor substrate 101 using at least one first contact plug 103; the second electrode pattern 106B is electrically connected to the second-conductivity well region 101P in the semiconductor substrate 101 using at least one second contact plug 104; and at least one second parasitic capacitance 108 is thus formed between the first-conductivity well region 101N and the second-conductivity well region 101P. Through the adding of the at least one second parasitic capacitance 108, the capacitance density of the capacitor structure 100 can be increased without increasing the number of metal layers in the three-dimensional structure of the capacitor structure 100, thereby saving the manufacturing cost of the capacitor structure 100.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A capacity structure, comprising:
a semiconductor substrate, comprising at least one first-conductivity well region and at least one second-conductivity well region adjacent to each other;
a first patterned conductive layer, disposed on the semiconductor substrate, and comprising a first electrode pattern and a second electrode pattern separated from each other and forming at least one first parasitic capacitance there between;
at least one first contact plug, electrically connecting the first electrode pattern and the at least one first-conductivity well region; and
at least one second contact plug, electrically connecting the second electrode pattern and the at least one second-conductivity well region, wherein at least one second parasitic capacitance is formed between the at least one first-conductivity well region and the at least one second-conductivity well region.

2. The capacity structure according to claim 1, further comprising a second patterned conductive layer disposed on the first patterned conductive layer, wherein the second patterned conductive layer comprises:
a third electrode pattern, electrically connected to the first electrode pattern; and
a fourth electrode pattern, electrically connected to the second electrode pattern and separated from the third electrode pattern, wherein at least one third parasitic capacitance is formed between the fourth electrode pattern and the third electrode pattern.

3. The capacity structure according to claim 1, where the at least one first-conductivity well region is an N-type doped well region; the at least one second-conductivity well region is a P-type doped well region.

4. The capacity structure according to claim 2, further comprising:
a first dielectric layer, disposed between the semiconductor substrate and the first patterned conductive layer, wherein the at least one first contact plug and the at least one second contact plug pass through the first dielectric layer;
a second dielectric layer, disposed between the first patterned conductive layer and the second patterned conductive layer;
at least one third contact plug, passing through the second dielectric layer and electrically connecting the first electrode pattern and the third electrode pattern; and
at least a fourth contact plug, passing through the second dielectric layer and electrically connecting the second electrode pattern and the fourth electrode pattern.

5. The capacity structure according to claim 1, wherein the semiconductor substrate further comprises a first deeply doped well region connecting the at least one first-conductivity well region and the at least one second-conductivity well region.

6. The capacity structure according to claim 1, wherein the at least one second parasitic capacitance is substantially smaller than the at least one first parasitic capacitance.

7. The capacity structure according to claim 6, wherein the at least one second parasitic capacitance is substantially 50% of the at least one first parasitic capacitance.

8. The capacity structure according to claim 1, wherein the first electrode pattern and the second electrode pattern are two finger-shaped electrode patterns arranged adjacent to each other in an intersecting manner.

9. The capacity structure according to claim 8, wherein the first electrode pattern comprises a plurality of first finger portions and a first connection portion connecting to the plurality of first finger portions; the second electrode pattern comprises a plurality of second finger portions and a second connection portion connecting to the plurality of second finger portions; and the plurality of first finger portions and the plurality of second finger portions are arranged in a staggered manner with each other.

10. The capacity structure according to claim 9, wherein the at least one first-conductivity well region comprises a plurality of first-conductivity strips; the at least one second-conductivity well region comprises a plurality of second-conductivity strips separated from each other and staggered with the plurality of first-conductivity strips; each of the plurality of first finger portions is electrically connected to a corresponding one of the plurality of first-conductivity strips through the at least one first contact plug; and each of the plurality of second finger portions is electrically connected to a corresponding one of the plurality of second-conductivity strips through the at least one second contact plug.

11. The capacity structure according to claim 10, wherein each of the plurality of first finger portions is vertically arranged above the corresponding one of the plurality of first-conductivity strips.

12. The capacity structure according to claim 11, wherein each of the plurality of first finger portions has a first lateral width less than a second lateral width the corresponding one of the plurality of first-conductivity strips.

13. The capacity structure according to claim 12, wherein a ratio of the first lateral width to the second lateral width is substantially between 0.25 to 0.75.

14. A method for manufacturing a capacity structure, comprising:
providing a semiconductor substrate, comprising a first-conductivity well region and a second-conductivity well region adjacent to each other;
forming a first patterned conductive layer on the semiconductor substrate, wherein the first patterned conductive layer comprises a first electrode pattern and a second electrode pattern separated from each other and forming at least one first parasitic capacitance there between;
forming at least one first contact plug, electrically connecting the first electrode pattern and the first-conductivity well region; and
forming at least one second contact plug, electrically connecting the second electrode pattern and the second-conductivity well region, wherein at least one second parasitic capacitance is formed between the first-conductivity well region and the second-conductivity well region.

15. The method according to claim 14, prior to forming the first patterned conductive layer, further comprising forming a first dielectric layer on the semiconductor substrate, allowing the at least one first contact plug and the at least one second contact plug passing through the first dielectric layer.

16. The method according to claim 14, further comprising:
forming a second dielectric layer on the first patterned conductive layer;
forming a second patterned conductive layer on the second dielectric layer to make the second patterned conductive layer comprising a third electrode pattern and a fourth electrode pattern separated from each other;
forming at least one third contact plug, passing through the second dielectric layer and electrically connecting the first electrode pattern and the third electrode pattern; and
forming at least a fourth contact plug, passing through the second dielectric layer and electrically connecting the second electrode pattern and the fourth electrode pattern.
